(19) United States
(12) Patent Application Publication
(10) Pub. No.: US 2010/0231769 A1
(43) Pub. Date: Sep. 16, 2010

(54) SOLID-STATE IMAGING DEVICE, IMAGING APPARATUS, AND DRIVING METHOD OF SOLID-STATE IMAGING DEVICE

(75) Inventors: Makoto SHIZUKUISHI, Kanagawa (JP); Motoari OTA, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/719,544

(22) Filed: Mar. 8, 2010

(30) Foreign Application Priority Data
Mar. 10, 2009 (JP) 2009-056386

(51) Int. Cl. H04N 5/335

(52) U.S. Cl. 348/306; 348/308

(57) ABSTRACT

A solid-state imaging device includes: a plurality of pixel portions each comprising a photoelectric conversion portion disposed in a semiconductor substrate; and a light shield layer disposed over the semiconductor substrate and having openings which are located over parts of the photoelectric conversion portions, respectively, each of the pixel portions further includes: a transistor comprising a gate electrode, a channel region, and a charge storage portion which is located between the semiconductor substrate and the gate electrode and stores charge generated in the photoelectric conversion portion, the channel region and the charge storage portion are covered with the light shield layer, and the photoelectric conversion portion extends to under the channel region of the transistor.

### CROSS-REFERENCE TO RELATED APPLICATIONS

This application claims the benefit of Japanese Patent Application JP 2009-056386, filed Mar. 10, 2009, the entire content of which is hereby incorporated by reference, the same as if set forth at length.

### FIELD OF THE INVENTION

The present invention relates to a solid-state imaging device, an imaging apparatus, and a driving method of a solid-state imaging device.

### BACKGROUND OF THE INVENTION

Conventionally, solid-state imaging devices have been proposed which are characterized in that charge generated through photoelectric conversion is stored in a nonvolatile MOS memory transistor having a charge storage portion such as a floating gate and a signal corresponding to the charge is read out (refer to JP-A-2001-85660 and JP-A-2002-280537, for example).

In the solid-state imaging device disclosed in JP-A-2001-85660, to attain miniaturization, a substrate region right under the charge storage layer of each nonvolatile memory transistor is used as a photoelectric conversion region. In this configuration, to allow incidence of light on the photoelectric conversion region, alight shield layer is formed on the substrate so as to have an opening in the area of each nonvolatile memory transistor and the gate electrode and the floating gate of each nonvolatile memory transistor is made of a transparent material. However, this configuration imbalance in color reproduction (white balance) because the gate electrode particularly obstructs entrance of short-wavelength light (e.g., blue light) to a large extent while transmitting long-wavelength light (e.g., red light) to cause its increased contribution to the sensitivity. Furthermore, the amount of incident light that is shielded by the gate electrode varies widely depending on its incident angle, resulting in luminance and color shading. In addition, at the time of signal reading, it is necessary to prevent entrance of light into each nonvolatile memory transistor by a mechanical shutter. This increases the cost of a camera incorporating the solid-state imaging device.

In contrast, in solid-state imaging device disclosed in JP-A-2002-280537, a photoelectric conversion region is formed beside each nonvolatile memory transistor and an opening of a light shield layer is formed over the photoelectric conversion region. This configuration can solve the problems of imbalance in color representation and luminance and color shading because incident light does not enter the photoelectric conversion region directly. Furthermore, since each nonvolatile memory transistor is shielded from light, no mechanical shutter is necessary, which lower the cost of a camera incorporating the solid-state imaging device.

### SUMMARY OF THE INVENTION

As described above, the solid-state imaging device disclosed in JP-A-2002-280537 is superior in many aspects to that disclosed in JP-A-2001-85660 and is highly useful. In the solid-state imaging device disclosed in JP-A-2002-280537 in which each photoelectric conversion element can generate the same amount of charge as in general CMOS image sensors, it is important how efficiently generated charge can be injected into the floating gate.

The present invention has been made under the above circumstances, and an object of the invention is to provide a solid-state imaging device which makes it possible to increase the efficiency of injection of charge generated through photoelectric conversion into a charge storage portion, its driving method, and an imaging apparatus using it.

The invention provides a solid-state imaging device comprising plural pixel portions each comprising a photoelectric conversion portion formed in a semiconductor substrate; and a light shield layer disposed over the semiconductor substrate and having openings which are located over parts of the photoelectric conversion portions, respectively, each of the pixel portions further comprising a transistor having a gate electrode, a channel region, and a charge storage portion which is located between the semiconductor substrate and the gate electrode and stores charge generated in the photoelectric conversion portion, the channel region and the charge storage portion being covered with the light shield layer, wherein the photoelectric conversion portion extends to under the channel region of the transistor.

The invention also provides an imaging apparatus comprising the above imaging device.

The invention further provides a driving method of an imaging device, comprising a charge injection control step of performing a control for injecting the charge into the charge storage portion from the photoelectric conversion portion by driving the transistor; and a signal reading control step of performing a control for reading out a variation in a threshold voltage of the transistor as a signal, wherein during the injection of the charge the charge injection control step applies a voltage to the gate electrode of the transistor and applies, to the source region and the drain region of the transistor, voltages that are opposite in polarity to the voltage applied to the gate electrode.

The invention can provide a solid-state imaging device which makes it possible to increase the efficiency of injection of charge generated through photoelectric conversion into a charge storage portion, its driving method, and an imaging apparatus using it.

### BRIEF DESCRIPTION OF THE DRAWINGS

FIG. 1A is a schematic plan view showing a general configuration of a solid-state imaging device according to an embodiment of the present invention, and FIG. 1B is a block diagram of each reading circuit.

FIG. 2 is a schematic plan view showing an example layout of each of pixel portions shown in FIG. 1A.

FIG. 3 is a schematic sectional view taken along line A-A′ in FIG. 2.

FIG. 4 is a schematic sectional view taken along line B-B′ in FIG. 2.

FIG. 5 is an equivalent circuit diagram of the pixel portion of FIG. 2.

FIG. 6 is a timing chart for description of a driving method of the solid-state imaging device of FIGS. 1A and 1B.

FIG. 7 is a schematic plan view of each pixel portion of a first modification of the solid-state imaging device of FIGS. 1A and 1B.

FIG. 8 is a schematic sectional view taken along line A-A′ in FIG. 7.

FIG. 9 is a schematic sectional view taken along line B-B′ in FIG. 7.

FIG. 10 is a schematic sectional view of a second modification of the solid-state imaging device of FIGS. 1A and 1B.

FIG. 11 is a schematic sectional view of a second modification of the solid-state imaging device of FIGS. 1A and 1B.

### DETAILED DESCRIPTION OF THE INVENTION

A solid-state imaging device according to an embodiment of the present invention will be hereinafter described with reference to the drawings. This solid-state imaging device is for use in an imaging unit of an imaging apparatus such as a digital camera or a digital video camera, a cell phone, an electronic endoscope, or the like.

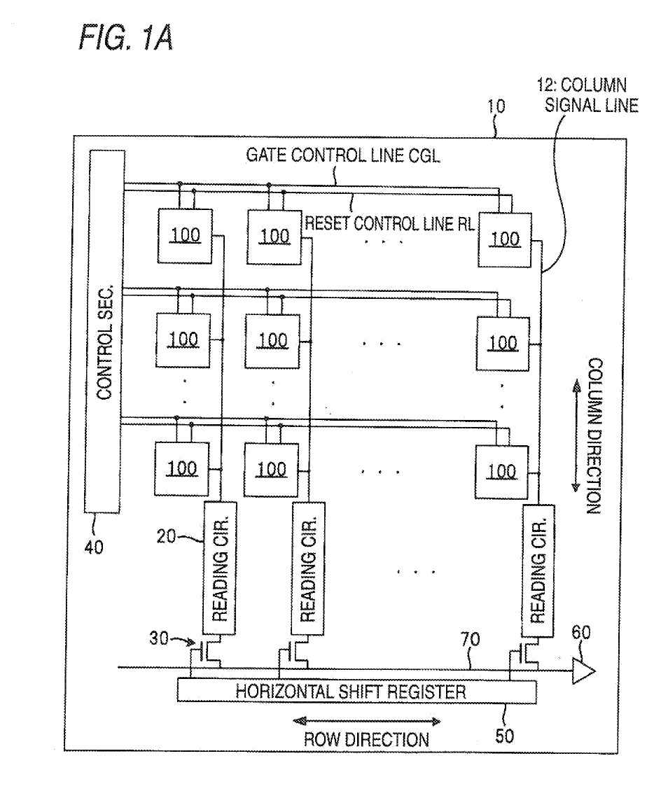

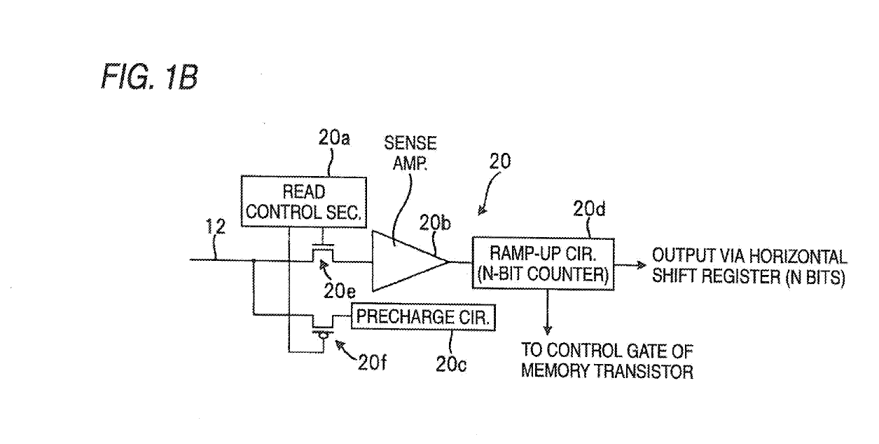

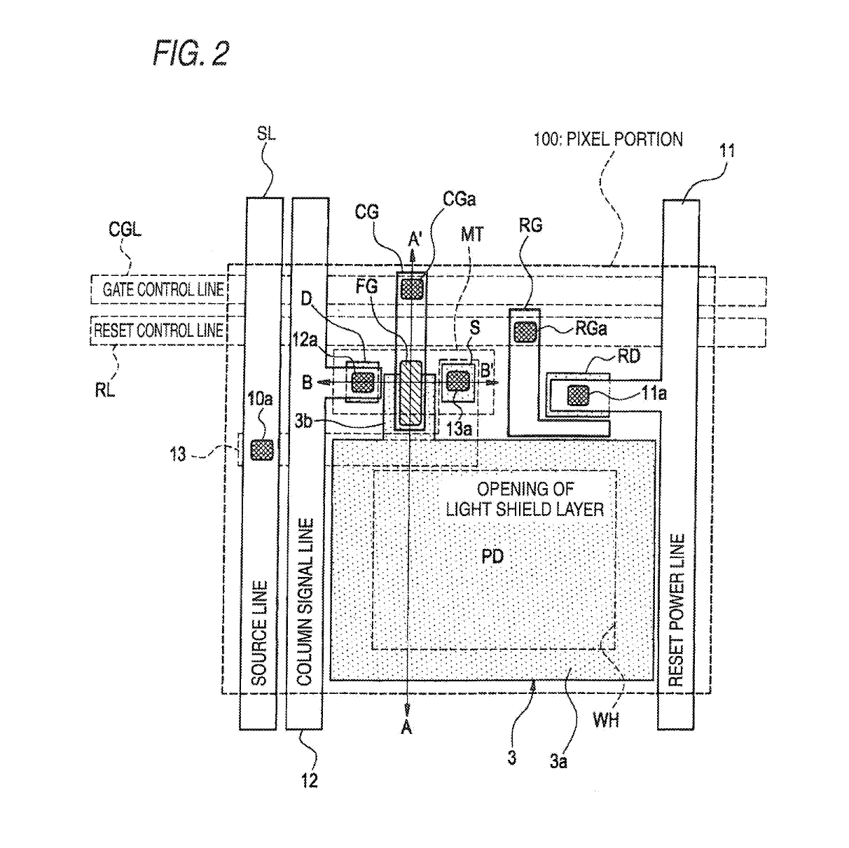

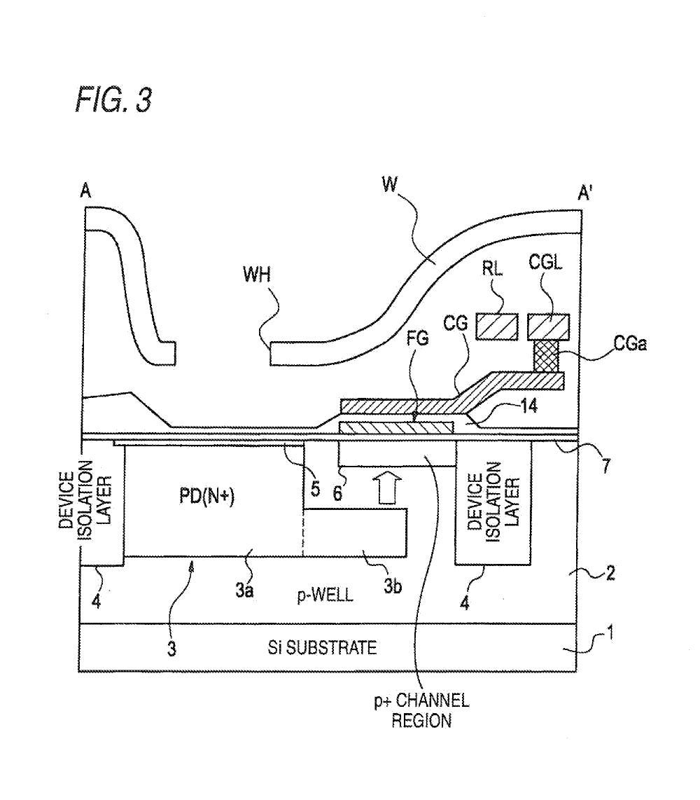

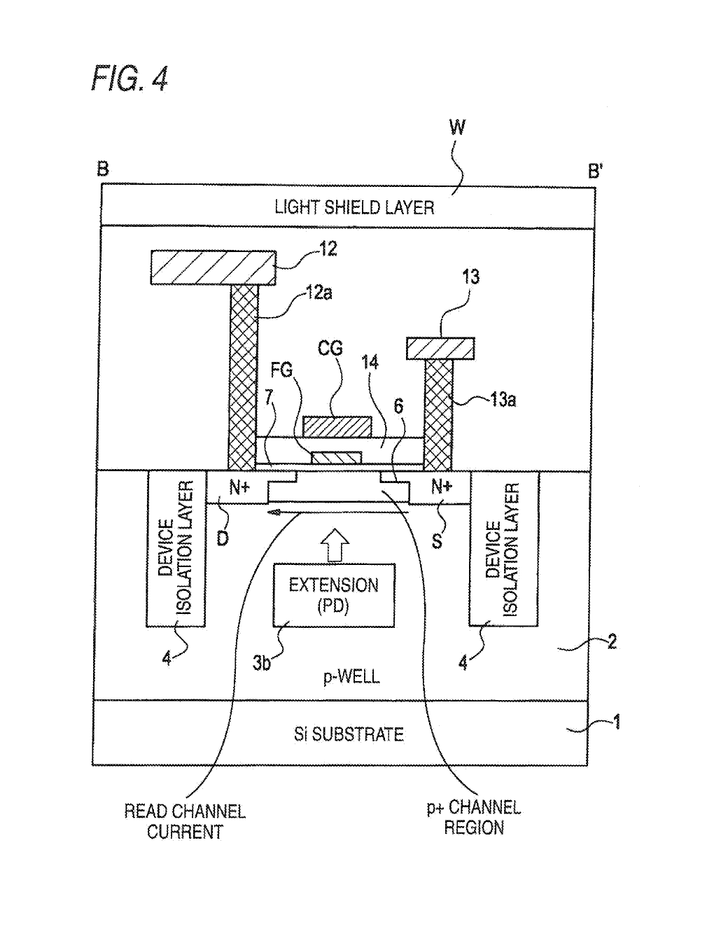

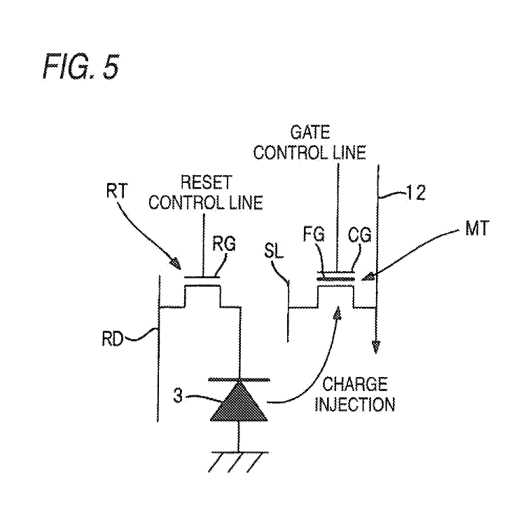

FIG. 1A is a schematic plan view showing a general configuration of the solid-state imaging device according to the embodiment of the invention, and FIG. 1B is a block diagram of each reading circuit. FIG. 2 is a schematic plan view showing an example layout of each of pixel portions shown in FIG. 1A. FIG. 3 is a schematic sectional view taken along line A-A′ in FIG. 2. FIG. 4 is a schematic sectional view taken along line B-B′ in FIG. 2. FIG. 5 is an equivalent circuit diagram of the pixel portion of FIG. 2.

The solid-state imaging device 10 is provided with plural pixel portions 100 which are arranged in the same plane in a row direction and a column direction that is perpendicular to the row direction so as to form an array (in this example, a square lattice).

Each pixel portion 100 is provided with an n-type impurity layer 3 which is formed in a semiconductor substrate which consists of an n-type silicon substrate 1 and a p-well layer 2 formed in the n-type silicon substrate 1. The n-type impurity layer 3 is formed in the p-well layer 2, and a photodiode (PD) which functions as a photoelectric conversion portion is formed by the pn junction of the n-type impurity layer 3 and the p-well layer 2. In the following description, the n-type impurity layer 3 will be referred to as a photoelectric conversion portion 3. The photoelectric conversion portion 3 is what is called a buried photodiode in which a p-type impurity layer 5 is formed adjacent to the surface for the purpose of complete depletion and suppression of dark current.

As shown in FIG. 5, each pixel portion 100 includes, in addition to the photoelectric conversion portion 3, a nonvolatile memory transistor MT including a floating gate FG as a charge storage portion which is formed on the semiconductor substrate and serves to store charge generated in the photoelectric conversion portion 3 and a reset transistor RT for ejecting charge stored in the photoelectric conversion portion 3 to a reset drain region RD.

Adjoining pixel portions 100 are isolated from each other by a device isolation layer 4 formed in the p-well layer 2. Example device isolation methods are a LOCOS (local oxidation of silicon) method, an STI (shallow trench isolation) method, and a high-concentration impurity ion implantation method.

The nonvolatile memory transistor MT has a MOS transistor structure and is provided with a source region S which is an n-type impurity region and is formed adjacent to the photoelectric conversion portion 3 so as to be spaced from it, a drain region D which is an n-type impurity region and is formed adjacent to the photoelectric conversion portion 3 so as to be spaced from it, a channel region 6 which is a p-type impurity region and is formed between the source region S and the drain region D, the floating gate FG which is formed on the semiconductor substrate with an oxide layer 7 interposed in between so as to be located between the source region S and the drain region D and to float electrically, and a control gate CG (gate electrode) which is formed over the floating gate FG with an insulating layer 14 interposed in between. The channel region 6 is a region where carriers flow when the voltage applied to the control gate CG has a prescribed value. Although in this example the channel region 6 is formed by implanting a p-type impurity into the region between the source region S and the drain region D, this region may be merely part of the p-well layer 2.

For example, the conductive material of the control gate CG may be polysilicon or doped polysilicon that is doped with phosphorus (P), arsenic (As), or boron (B) at a high concentration. Alternatively, the control gate CG may be made of a silicide of such a metal as titanium (Ti) or tungsten (W) or have a salicide (self-align silicide) structure. The conductive material of the floating gate FG may be the same as that of the control gate CG.

In the example layout of FIG. 2, the source region S and the drain region D are arranged in the row direction and the floating gate FG and the control gate CG are formed between the source region S and the drain region D so as extend long in the column direction. The control gate CG extends to under a gate control line CGL which is an aluminum interconnection extending in the row direction, and is connected to it by a contact CGa which is made of aluminum or the like. The gate control lines CGL are provided for respective lines of pixel portions 100 that are arranged in the row direction. The gate control lines CGL for the respective lines of pixel portions 100 are connected to a control section 40 so that voltages can be applied independently to the respective lines of pixel portions 100.

Part of a column signal line 12 which is an aluminum interconnection extending in the column direction projects to over the drain region D and is electrically connected to the drain region D by a contact 12a which is made of aluminum or the like. The column signal lines 12 are provided for respective sets of pixel portions 100 that are arranged in the column direction, and are connected to respective reading circuits 20 (described later).

A contact 13a which is made of aluminum or the like is formed on the source region S and an interconnection 13 is connected to the contact 13a. The interconnection 13 passes under the column signal line 12 and extends to under a source line SL which is an aluminum interconnection that is adjacent to the column signal line 12 on the left. The interconnection 13 is electrically connected to the source line SL by a contact 10a which is made of aluminum or the like. The source lines SL are provided for the respective sets of pixel portions 100 that are arrange in the column direction, and are given a prescribed potential (e.g., ground potential).

The reset transistor RT has a MOS transistor structure and is provided with the photoelectric conversion portion 3 which functions as a source region, a drain region RD which is an n-type impurity region and is formed adjacent to the photoelectric conversion portion 3 so as to be spaced from it, and a reset gate RG which is formed on the semiconductor substrate between the photoelectric conversion portion 3 and the drain region RD with the oxide layer 7 interposed in between.

In the example layout of FIG. 2, the reset gate RG extends to under a reset control line RL which is an aluminum interconnection extending in the row direction and is connected to the reset control line RL by a contact RGa which is made of aluminum or the like. The reset control lines RL are provided for the respective lines of pixel portions 100 that are arranged in the row direction. The reset control lines RL for the respective lines of pixel portions 100 are connected to the control section 40 so that voltages can be applied independently to the respective lines of pixel portions 100. When a reset pulse is applied to the reset transistor RT from the control section 40 via the reset line RL, the reset transistor RT is turned on and charge stored in the photoelectric conversion portion 3 is ejected to the drain region RD of the reset transistor RT.

Part of a reset power line 11 which is an aluminum interconnection extending in the column direction extends to over the drain region RD, and is electrically connected to the drain region RD by a contact 11a which is made of aluminum or the like. The reset power lines 11 are provided for the respective sets of pixel portions 100 that are arranged in the column direction, and are supplied with a prescribed power source voltage.

The locations of the reset transistor RT and the nonvolatile memory transistor MT are not limited to the ones shown in FIG. 2 and may be determined according to available spaces.

Returning to FIG. 1A, the solid-state imaging device 10 is equipped with the control section 40 for controlling the nonvolatile memory transistors MT, the reading circuits 20 for detecting threshold voltages of the respective nonvolatile memory transistors MT, a horizontal shift register 50 for performing a control for sequentially reading, into a signal line 70, as imaging signals, I-line threshold voltages detected by the respective reading circuits 20, and an output amplifier 60 which is connected to the signal line 70.

Each reading circuit 20 is provided for the corresponding pixel portions 100 that are arranged in the column direction, and connected to the drain regions D of the nonvolatile memory transistors MT of those pixel portions 100 by the column signal line 12. The reading circuits 20 are also connected to the control section 40.

As shown in FIG. 1B, each reading circuit 20 is equipped with a read control section 20a, a sense amplifier 20b, a precharge circuit 20c, a ramp-up circuit 20d, and transistors 20e and 20f.

In reading an imaging signal from one corresponding pixel portion 100, the read control circuit 20a turns on the transistor 20f so that a drain voltage is supplied from the precharge circuit 20c to the drain region D of the nonvolatile memory transistor MT of the pixel portions 100 via the column signal line 12 (precharging). Then, the read control circuit 20a turns on the transistor 20e to render the drain region D of the nonvolatile memory transistor MT of the pixel portion 100 electrically continuous with the sense amplifier 20b.

Monitoring the voltage of the drain region D of the pixel portion 100, the sense amplifier 20b detects a change in the voltage and informs the ramp-up circuit 20d of the change. For example, the sense amplifier 20b detects a drop of the drain voltage of the precharging by precharge circuit 20c and inverts the sense amplifier output.

Incorporating an N-bit counter (N=8 to 12, for example), the ramp-up circuit 20d supplies a ramp voltage which increases or decreases gradually to the control gate CG of the pixel portion 100 via the control section 40 and outputs a count (a combination of is and 0s (N in total number)) corresponding to the value of the ramp voltage.

If the voltage of the control gate CG becomes higher than the threshold voltage of the nonvolatile memory transistor MT, the nonvolatile memory transistor MT is rendered conductive and, at that time, the potential of the column signal line 12 that has been precharged drops. The sense amplifier detects this event and outputs an inversion signal. The ramp-up circuit 20d latches a count corresponding to a value of the ramp voltage at a time point of reception of the inversion signal. In this manner, the variation in the threshold voltage can be read out as an imaging signal which is a digital value (i.e., a combination of is and 0s).

When one horizontal selection transistor 30 is selected by the horizontal shift register 50, a count that is latched by the ramp-up circuit 20d connected to the selected horizontal selection transistor 30 is output to the signal line 70 and then output from the output amplifier 60 as an imaging signal.

The method for reading out a change in the threshold voltage of the nonvolatile memory transistor MT by each reading circuit 20 is not limited to the above one. For example, a drain current of the nonvolatile memory transistor MT when certain voltages are applied to the control gate CG and the drain region D may be read out as an imaging signal.

The control section 40 controls the nonvolatile memory transistor MT and thereby performs driving for injecting charge generated in the photoelectric conversion portion 3 into the floating gate FG and storing the charge in the floating gate FG. In the photoelectric conversion portion 3, when a write pulse is applied to the control gate CG, charge generated in the photoelectric conversion portion 3 is injected into and stored in the floating gate FG by F-N tunneling injection in which charge is injected using a Fowler-Nordheim (F-N) tunneling current, direct tunneling injection, or the like.

The control section 40 controls the nonvolatile memory transistor MT and the reading circuits 20 by the above-described method and thereby performs driving for reading out an imaging signal corresponding to charge that is stored in the floating gate FG.

The control section 40 also performs reset driving for rendering the photoelectric conversion portion 3 empty by ejecting charge that has been generated and stored in the photoelectric conversion portion 3 until immediately before an exposure period (i.e., a period in which the photoelectric conversion portion 3 is exposed to obtain an imaging signal to be used for generating one image data) of the pixel portion 100 and charge erasure driving for erasing charge stored in the floating gate FG by ejecting it to the semiconductor substrate.

As for the positional relationships between the various interconnections, the source line SL, the reset power line 11, and the column signal line 12 are located above the gate control line CGL, the reset control line RL, and the interconnection 13.

A light shield layer W of tungsten or the like is formed so that light does not enter each pixel portion 100 except for part of the photoelectric conversion portion 3. As shown in FIGS. 2 and 3, the light shield layer W having an opening WH over part of the photoelectric conversion portion 3 is formed above the semiconductor substrate (above the source line SL, the reset power line 11, and the column signal line 12).

To increase the efficiency of injection of charge into the floating gate FG, as shown in FIGS. 2 and 3, the most important feature of the solid-state imaging device 10 is that the photoelectric conversion portion 3 not only exists under the opening WH of the light shield layer W but also extends to under the channel region 6 of the nonvolatile memory transistor MT.

As shown in FIG. 3, the photoelectric conversion portion 3 consists of a main portion 3a which is formed under the opening WH and an extension 3b which projects from the main portion 3a so as to extend to under the channel region 6. Although a boundary line (broken line) is drawn in FIG. 3 between the main portion 3a and the extension 3b, this is just for the convenience of description and actually no such line exists.

The main portion 3a is a portion that is formed under the opening WH and serves to receive light. The extension 3b is a portion that projects from the main portion 3a so as to extend to under the channel region 6 of the nonvolatile memory transistor MT inside the p-well layer 2. In a plan view, the extension 3b extends in the column direction from the position of the main portion 3a that is opposed to the area that is located between the source region S and the drain region D to that area. That is, the photoelectric conversion portion 3 is formed so as to exist, in a plan view, only under the channel region 6 of the nonvolatile memory transistor MT in the area where the nonvolatile memory transistor MT and the reset transistor RT are formed.

Since the channel region 6 is located right under the control gate CG and the floating gate FG, forming the photoelectric conversion portion 3 so that it extends to under the channel region 6 (preferably to the entire area where it could coextend with the channel region 6) makes it possible to apply an electric field to the floating gate FG from the photoelectric conversion portion 3 approximately perpendicularly by applying a voltage (CG voltage) to the control gate CG in injecting charge into the floating gate FG from the photoelectric conversion portion 3 by F-N tunneling injection or direct tunneling injection. As a result, the charge in the photoelectric conversion portion 3 is accelerated more easily toward the control gate CG and hence tunneling for producing the same tunneling current can be caused at a lower CG voltage than in conventional techniques. In the conventional techniques, although part of the photoelectric conversion portion extend to under the control gate and the floating gate, because of the necessity to secure a sufficiently large channel region of the transistor, it is difficult to widen the overlap between the photoelectric conversion portion and the control gate. As a result, when a voltage is applied to the control gate, an electric field develops obliquely between the photoelectric conversion portion and the floating gate and hence tunneling current may not be generated efficiently. In contrast, in the solid-state imaging device 10, since the photoelectric conversion portion 3 extends to under the channel region 6 while the channel region 6 is made sufficiently large, there is no limitation on the size of the overlap between the photoelectric conversion portion 3 and the control gate CG. The electric field direction can be made approximately perpendicular to the floating gate FG and tunneling current can be generated efficiently.

The length of the photoelectric conversion portion 3 in the direction parallel with the substrate surface can be controlled by adjusting a mask pattern that is used for ion implantation, and its length in the direction perpendicular to the substrate surface can be controlled by controlling the ion implantation energy. In this manner, the photoelectric conversion portion 3 consisting of the main portion 3a and the extension 3b can be formed.

Next, a driving method of the solid-state imaging device 10 having the above configuration will be described.

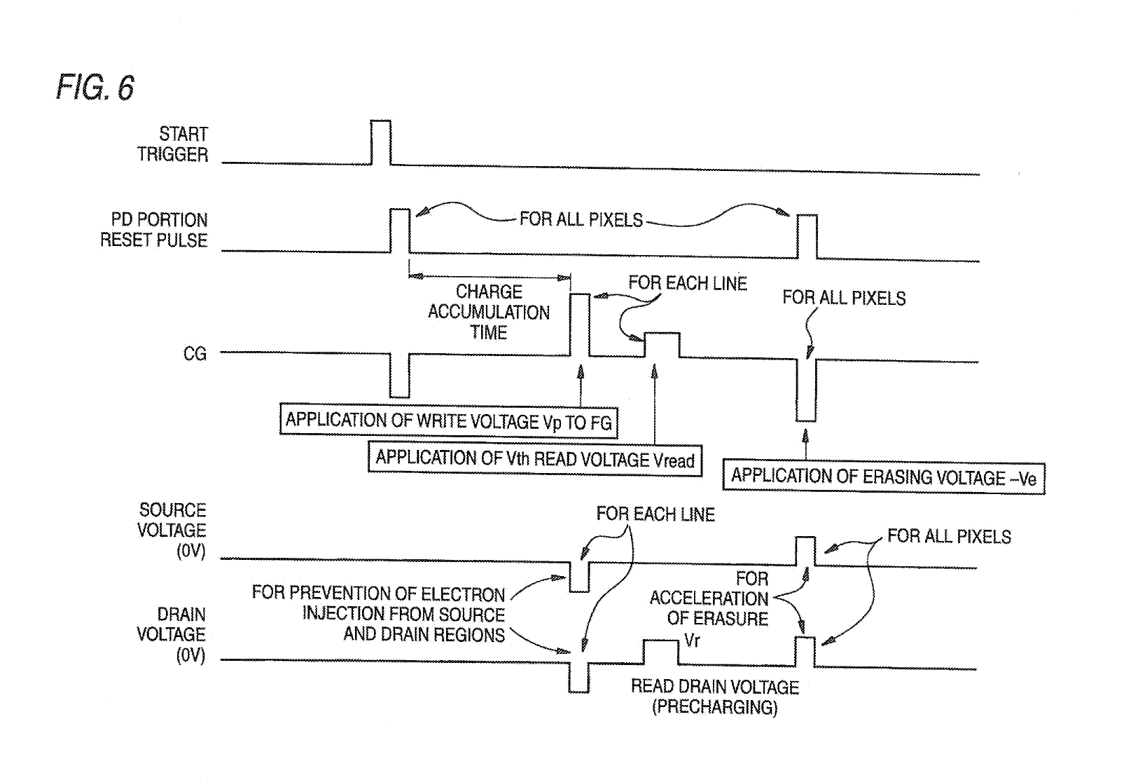

FIG. 6 is a timing chart for description of a driving method of the solid-state imaging device 10 of FIGS. 1A and 1B. FIG. 6 shows how voltages supplied to individual portions of each of pixel portions 100 of an arbitrary line varies with time.

In the solid-state imaging device 10, upon reception of a shooting instruction, the control section 40 supplies a reset pulse to the reset gate RG of the reset transistor RT of every pixel portion 100 using the shooting instruction as a start trigger. In response, unnecessary charge stored in the photoelectric conversion portion 3 is ejected to the drain region RD of the reset transistor RT and an exposure period (charge accumulation period) is started in every pixel portion 100.

After the end of the exposure period, the control section 40 supplies a write voltage Vp to the control gate CG of every pixel portion 100 to cause charge generated in the photoelectric conversion portion 3 during the exposure period to be injected into the floating gate FG. The charge accumulated in the photoelectric conversion portion 3 is moved from the main portion 3a to the extension 3b and injected into the floating gate FG from the extension 3b via the channel region 6. As for the method for supplying the write voltage Vp, either of a method that the supply of the write voltage Vp is started at the same time as the end of the exposure period and a method that the supply of the write voltage Vp is started at the same time as the start of the exposure period and is finished at the same time as the end of the exposure period may be employed.

At the same time as the application of the write voltage Vp, the control section 40 applies voltages that are opposite in polarity to the write voltage Vp to the source region S and the drain region D of the nonvolatile memory transistor MT of every pixel portion 100. This suppresses injection of charge from the source region S and the drain region D to the floating gate FG in the period when charge is injected into the floating gate FG from the photoelectric conversion portion 3. The application of these voltages to the source region S and the drain region D is not indispensable. These voltages may be applied by providing circuits for applying voltages to the source line SL and the column signal line 12 (the circuit for applying a voltage to the column signal line 12 may be the precharge circuit 20c) or constructing the control section 40 so that it can apply these voltages.

After the end of the charge injection into the floating gates FG, the control section 40 sets the drain potential of the nonvolatile memory transistor MT of each pixel portion 100 of the first line to Vr (precharging) and starts application of a ramp voltage (read voltage Vread) to the control gate CG of each pixel portion 100 of the first line. A count corresponding to a value of the ramp voltage at a time point when the drain potential of the nonvolatile memory transistor MT of each pixel portion 100 of the first line has dropped is latched in the corresponding reading circuit 20 and output from the output amplifier 60 as an imaging signal. The control section 40 performs the same driving for the second and following lines, whereby imaging signals corresponding to charges stored in the floating gates FG of all the lines are output.

After the output of the imaging signals from all the lines, the control section 40 applies a negative erasing voltage −Ve to the control gate CG of every pixel portion 100 and applies a positive voltage Vcc to the semiconductor substrate. As a result, the charges stored in the floating gates FG are erased being removed into the semiconductor substrate. At the same time as the application of the erasing voltage −Ve, the control section 40 voltages that are opposite in polarity to the erasing voltage −Ve to the source region S and the drain region D of the nonvolatile memory transistor MT of every pixel portion 100. This accelerates the charge removal from the floating gates FG into the semiconductor substrate. The application of these voltages to the source region S and the drain region D is not indispensable. These voltages may be applied by providing circuits for applying voltages to the source line SL and the column signal line 12 (the circuit for applying a voltage to the column signal line 12 may be the precharge circuit 20c) or constructing the control section 40 so that it can apply these voltages.

After the erasure of the charges stored in the floating gates FG, the control section 40 sets the drain potential of the nonvolatile memory transistor MT of each pixel portion 100 of the first line to Vr (precharging) and starts application of a ramp voltage (read voltage Vread) to the control gate CG of each pixel portion 100 of the first line. A count corresponding to a value of the ramp voltage at a time point when the drain potential of the nonvolatile memory transistor MT of each pixel portion 100 of the first line has dropped is latched in the corresponding reading circuit 20 and output from the output amplifier 60 as an imaging signal. The control section 40 performs the same driving for the second and following lines, whereby imaging signals corresponding to charges stored in the floating gates FG of all the lines are output. As a result, the same black level of imaging signals as was obtained in the preceding exposure period can be obtained.

In the solid-state imaging device 10, since as described above the photoelectric conversion portion 3 extends to under the channel region 6 of the nonvolatile memory transistor MT, the efficiency of charge injection into the floating gate FG can be increased. This provides advantages of increase in sensitivity etc.

In the solid-state imaging device 10 in which the reset transistor RT is provided in each pixel portion 100, an electronic shutter can be realized by using the reset transistors RT. As a result, a solid-state imaging device having a mechanical-shutterless global shutter function can be realized. Unlike in the configurations of JP-A-2001-85660 and JP-A-2002-280537 in which charge injection into the floating gate FG and reading of an imaging signal are performed by plural transistors, in the solid-state imaging device 10 they are performed by the single nonvolatile memory transistor MT. That is, a solid-state imaging device having a mechanical-shutterless global shutter function can be realized merely by providing only two transistors (reset transistor RT and nonvolatile memory transistor MT) in each pixel portion 100. The number of transistors can be made smaller, the pixel miniaturization can be made easier, and the cost can be made lower than in configurations as would be obtained by adding a reset transistor to the configurations of JP-A-2001-85660 and JP-A-2002-280537.

In the solid-state imaging device 10, the area of each floating gate FG can be made smaller than in the configuration of JP-A-2002-280537 in which the function of the nonvolatile memory transistor MT is realized by two transistors. As a result, the threshold voltage variation of the nonvolatile memory transistor MT with respect to the amount of change injected into the floating gate FG can be increased and hence high photoelectric conversion efficiency can be obtained.

In the solid-state imaging device 10, the photoelectric conversion portion 3 and the nonvolatile memory transistor MT are formed so as to be completely independent of each other. Although a configuration in which the photoelectric conversion portion 3 and the nonvolatile memory transistor MT share a source region is possible as in the case of JP-A-2002-280537, the configuration in which the photoelectric conversion portion 3 and the nonvolatile memory transistor MT are independent of each other makes it possible to apply voltages for suppressing charge injection to the source region S and the drain region D of the nonvolatile memory transistor MT during an imaging signal reading period, which in turn makes it possible to suppress noise and increase the SN ratio. It is also possible to apply voltages for acceleration of charge erasure to the source region S and the drain region D in removing charge from the floating gate FG, which makes it possible to effectively prevent charge generated by the preceding exposure from remaining in the floating gate FG.

Modifications of the solid-state imaging device 10 will be described below.

### (First Modification)

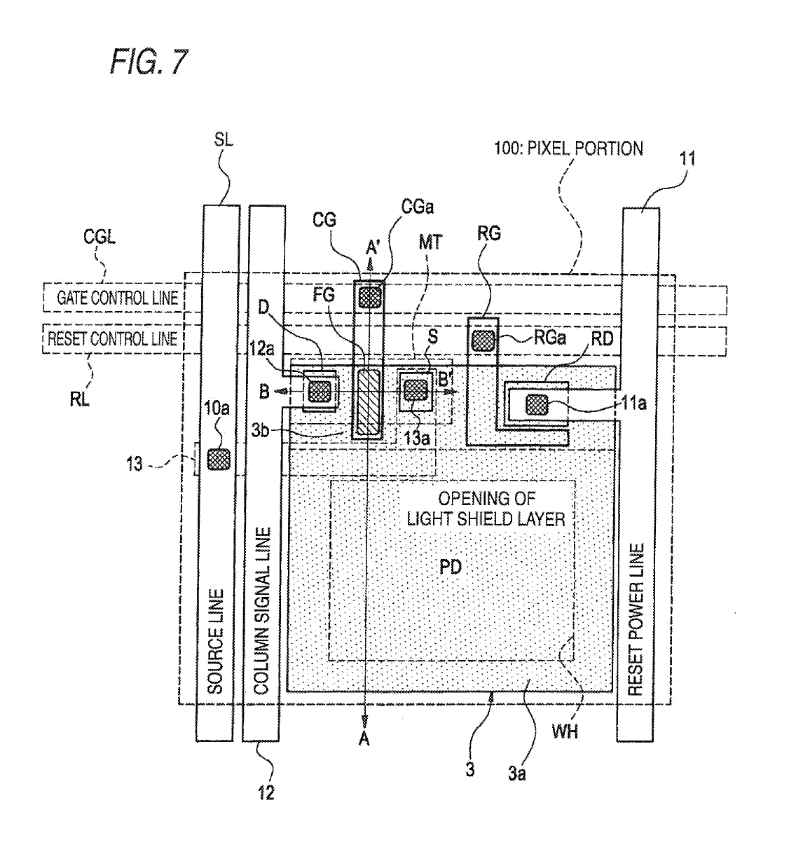

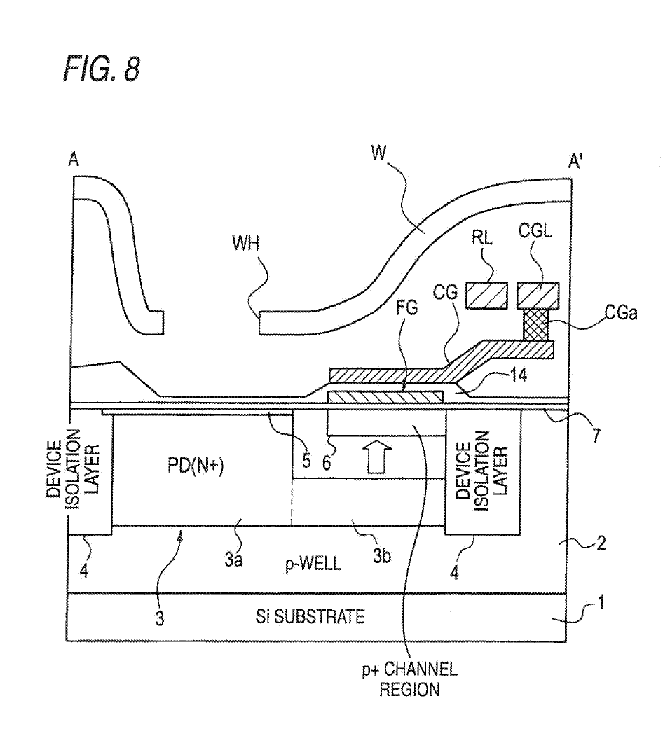

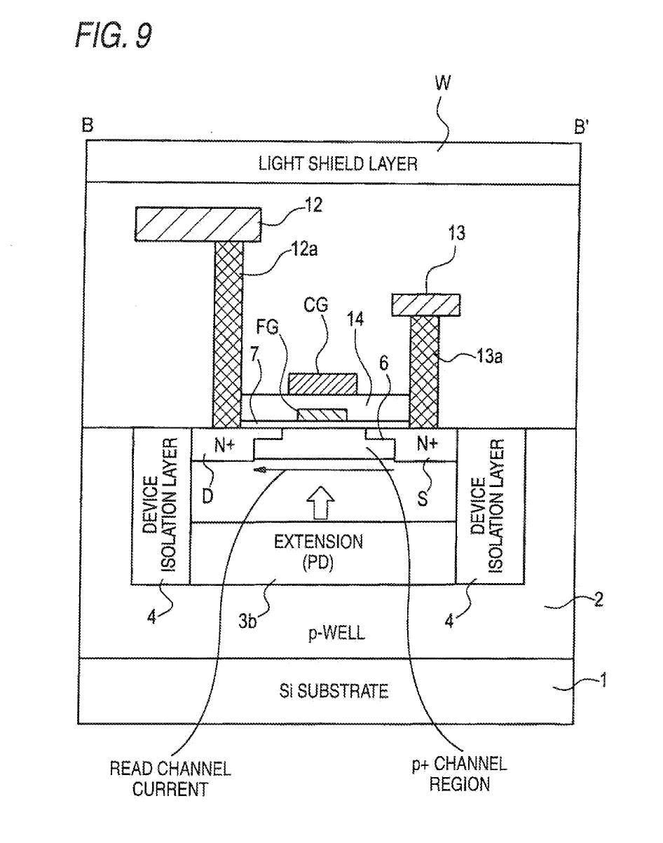

FIG. 7 is a schematic plan view of each pixel portion of a first modification of the solid-state imaging device 10 of FIGS. 1A and 1B. FIG. 8 is a schematic sectional view taken along line A-A′ in FIG. 7. FIG. 9 is a schematic sectional view taken along line B-B′ in FIG. 7.

In the solid-state imaging device 10 of FIGS. 1A and 1B, the part of the photoelectric conversion portion 3 extends so that in a plan view the photoelectric conversion portion 3 exists only under the channel region 6 of the nonvolatile memory transistor MT in the area where the nonvolatile memory transistor MT and the reset transistor RT exist. In contrast, in the solid-state imaging device of the first modification, the photoelectric conversion portion 3 extends so as to exist, in a plan view, also under the source region S, the drain region D, and the reset drain region RD.

Also in this configuration, the efficiency of charge injection into the floating gate FG can be increased.

### (Second Modification)

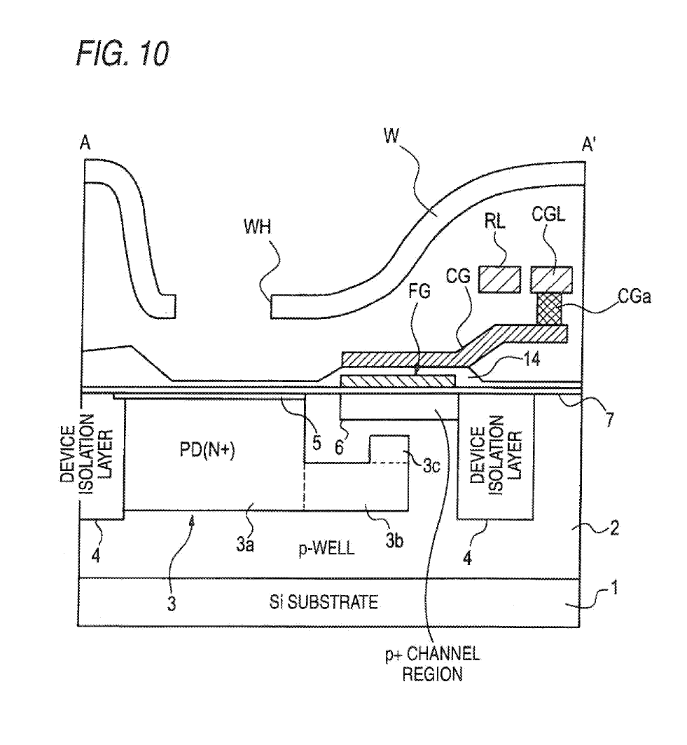

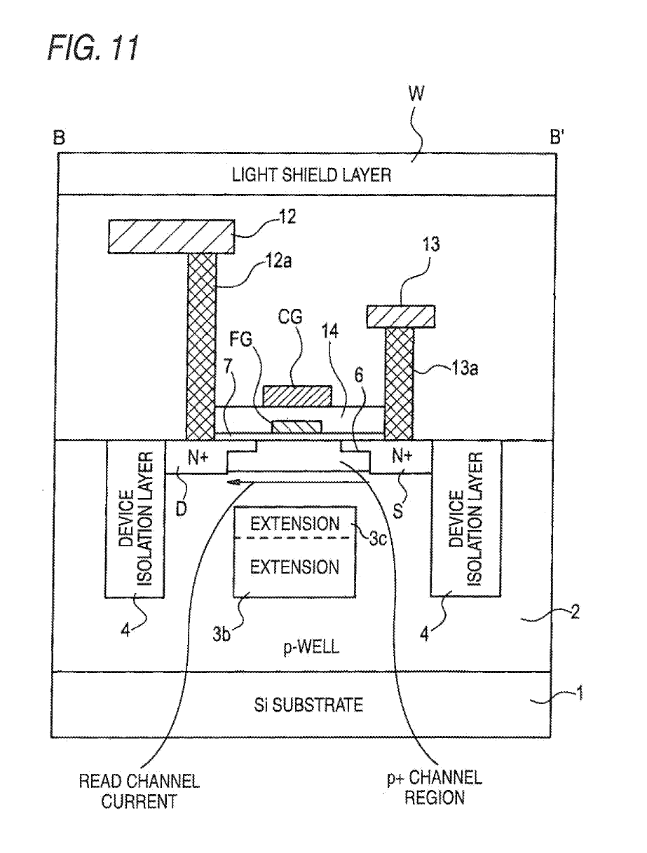

A schematic plan view a solid-state imaging device of a second modification is the same as FIG. 2 and for convenience reference will be made of FIG. 2. FIG. 10 is a schematic sectional view, taken along line A-A′ in FIG. 2, of the second modification of the solid-state imaging device 10 of FIGS. 1A and 1B. FIG. 11 is a schematic sectional view, taken along line B-B′ in FIG. 2, of the second modification of the solid-state imaging device 10 of FIGS. 1A and 1B. In FIGS. 10 and 11, portions having the same portions in FIGS. 3 and 4, respectively, are given the same reference symbols as the latter.

In the solid-state imaging device of the second modification, the photoelectric conversion portion 3 extends from under the opening WH to under the channel region 6 and further projects upward under the channel region 6 so as to come closer to the channel region 6. As shown in FIGS. 10 and 11, the photoelectric conversion portion 3 consists of a main portion 3a, an extension 3b which projects from a bottom portion of the main portion 3a so as to extend parallel with the semiconductor substrate surface to under the channel region 6, and an extension 3c which projects upward from a tip portion of the extension 3b so as to extend perpendicularly to the substrate surface toward the channel region 6. Although a boundary line (broken line) is drawn in FIGS. 10 and 11 between the extensions 3b and 3c, this is just for the convenience of description and actually no such line exists.

In this configuration, the portion of the photoelectric conversion portion 3 that coextends with the channel region 6 is closer to the channel region and hence charge can be injected more efficiently.

Although the above description is such that the nonvolatile memory transistor MT is the MOS transistor having the floating gate FG, the nonvolatile memory transistor MT may have a structure other than the MOS structure. For example, it is possible to employ an MNOS transistor structure in which the floating gate FG is a nitride layer and the control gate CG is formed directly on the nitride layer and a MONOS transistor structure in which the floating gate FG is a nitride layer. In either case, the nitride layer serves as a charge storage portion.

Although the above description assumes that charge to be handled (i.e., to be collected as a signal) is charge of electrons, the same concept applies even in the case where charge to be handled is charge of holes. Where charge to be handled is charge of holes, the n-type regions should be replaced by p-type regions and the polarities of the voltages that are applied to the individual portions should be reversed.

As described above, this specification discloses the following items:

A solid-state imaging device comprising plural pixel portions each comprising a photoelectric conversion portion formed in a semiconductor substrate; and a light shield layer disposed over the semiconductor substrate and having openings which are located over parts of the photoelectric conversion portions, respectively, each of the pixel portions further comprising a transistor having a gate electrode, a channel region, and a charge storage portion which is located between the semiconductor substrate and the gate electrode and stores charge generated in the photoelectric conversion portion, the channel region and the charge storage portion being covered with the light shield layer, wherein the photoelectric conversion portion extends to under the channel region of the transistor.

With this configuration, since a portion of the photoelectric conversion portion exists under the channel region of the transistor, charge that is generated in the photoelectric conversion portion according to the amount of light that shines on the photoelectric conversion portion through the opening of the light shield layer can be injected efficiently into the charge storage portion from that portion of the photoelectric conversion portion which coextends with the channel region through the channel region.

A solid-state imaging device in which the photoelectric conversion portion has, under the channel region, an extension which projects toward the channel region.

With this configuration, since the extension of the photoelectric conversion portion which coextends with the channel region is closer to the charge storage portion, charge can be injected more efficiently.

A solid-state imaging device in which each of the pixel portions further comprises a reset transistor for ejecting the charge stored in the photoelectric conversion portion to a drain region of the reset transistor.

This configuration makes it possible to control the exposure time of the photoelectric conversion portion without a mechanical shutter. Furthermore, since the number of transistors included in each pixel portion can be reduced to two at the minimum, each pixel portion can be the miniaturized more easily.

A solid-state imaging device in which a source region and a drain region of the transistor are formed independently of the photoelectric conversion portion.

With this configuration, since the photoelectric conversion portion and the transistor are completely independent of each other, an event that unnecessary charge is injected into the charge storage portion from the photoelectric conversion portion can be prevented even in, for example, the case of reading out a signal corresponding to charge from the charge storage portion in a state with no light illumination.

A solid-state imaging device in which in an area where the transistor is formed the photoelectric conversion portion is formed so as to exist only under the channel region which is located between the source region and the drain region.

This configuration can increase the charge injection efficiency.

A solid-state imaging device further comprising charge injection control means for performing a control for injecting the charge into the charge storage portion from the photoelectric conversion portion by driving the transistor; and signal reading control means for performing a control for reading out a variation in a threshold voltage of the transistor as a signal.

This configuration can make the number of transistors lower and hence the pixel miniaturization easier than in conventional configurations in which separate transistors are used for the charge injection and the signal reading. Furthermore, since the area of the charge storage portion is reduced, the threshold voltage variation with respect to the injected charge amount can be increased.

A solid-state imaging device further comprising charge injection control means for performing a control for injecting the charge into the charge storage portion from the photoelectric conversion portion by driving the transistor; and signal reading control means for performing a control for reading out a variation in a threshold voltage of the transistor as a signal, wherein during the injection of the charge the charge injection control means applies a voltage to the gate electrode of the transistor and applies, to the source region and the drain region of the transistor, voltages that are opposite in polarity to the voltage applied to the gate electrode.

This configuration can suppress a phenomenon that charge is injected into the charge storage portion from the source region and the drain region during charge injection into the charge storage portion from the photoelectric conversion portion, and hence can reduce noise.

A solid-state imaging device further comprising charge erasing means for erasing the charge stored in the charge storage portion by removing it into the semiconductor substrate, wherein during the removal of the charge the charge erasing means applies a voltage to the gate electrode of the transistor and applies, to the source region and the drain region of the transistor, voltages that are opposite in polarity to the voltage applied to the gate electrode.

This configuration accelerates the charge removal and hence enables high-speed charge erasure. Furthermore, this configuration can prevent occurrence of residual charge.

An imaging apparatus comprising any of the above imaging devices.

A driving method of the imaging device, comprising a charge injection control step of performing a control for injecting the charge into the charge storage portion from the photoelectric conversion portion by driving the transistor; and a signal reading control step of performing a control for reading out a variation in a threshold voltage of the transistor as a signal, wherein during the injection of the charge the charge injection control step applies a voltage to the gate electrode of the transistor and applies, to the source region and the drain region of the transistor, voltages that are opposite in polarity to the voltage applied to the gate electrode.

A driving method of the imaging device, comprising a charge erasing step of erasing the charge stored in the charge storage portion by removing it into the semiconductor substrate, wherein during the removal of the charge the charge erasing step applies a voltage to the gate electrode of the transistor and applies, to the source region and the drain region of the transistor, voltages that are opposite in polarity to the voltage applied to the gate electrode.

What is claimed is:

1. A solid-state imaging device comprising:
a plurality of pixel portions each comprising a photoelectric conversion portion disposed in a semiconductor substrate; and
a light shield layer disposed over the semiconductor substrate and having openings which are located over parts of the photoelectric conversion portions, respectively, each of the pixel portions further comprising:
a transistor comprising a gate electrode, a channel region, and a charge storage portion which is located between the semiconductor substrate and the gate electrode and stores charge generated in the photoelectric conversion portion, the channel region and the charge storage portion being covered with the light shield layer,
wherein the photoelectric conversion portion extends to under the channel region of the transistor.

2. The solid-state imaging device according to claim 1, wherein the photoelectric conversion portion has, under the channel region, an extension which projects toward the channel region.

3. The solid-state imaging device according to claim 1, wherein each of the pixel portions further comprises a reset transistor for ejecting the charge stored in the photoelectric conversion portion to a drain region of the reset transistor.

4. The solid-state imaging device according to claim 1, wherein a source region and a drain region of the transistor are formed independently of the photoelectric conversion portion.

5. The solid-state imaging device according to claim 4, wherein in an area where the transistor is formed the photoelectric conversion portion is formed so as to exist only under the channel region which is located between the source region and the drain region.

6. The solid-state imaging device according to claim 1, further comprising:
a charge injection control unit for performing a control for injecting the charge into the charge storage portion from the photoelectric conversion portion by driving the transistor; and
a signal reading control unit for performing a control for reading out a variation in a threshold voltage of the transistor as a signal.

7. The solid-state imaging device according to claim 4, further comprising:
a charge injection control unit for performing a control for injecting the charge into the charge storage portion from the photoelectric conversion portion by driving the transistor; and
a signal reading control unit for performing a control for reading out a variation in a threshold voltage of the transistor as a signal,
wherein during the injection of the charge the charge injection control unit applies a voltage to the gate electrode of the transistor and applies, to the source region and the drain region of the transistor, voltages that are opposite in polarity to the voltage applied to the gate electrode.

8. The solid-state imaging device according to claim 4, further comprising a charge erasing unit for erasing the charge stored in the charge storage portion by removing it into the semiconductor substrate, wherein during the removal of the charge the charge erasing unit applies a voltage to the gate electrode of the transistor and applies, to the source region and the drain region of the transistor, voltages that are opposite in polarity to the voltage applied to the gate electrode.

9. An imaging apparatus comprising the imaging device according to claim 1.

10. A driving method of the imaging device according to claim 4, comprising:
a charge injection control step of performing a control for injecting the charge into the charge storage portion from the photoelectric conversion portion by driving the transistor; and
a signal reading control step of performing a control for reading out a variation in a threshold voltage of the transistor as a signal,
wherein during the injection of the charge the charge injection control step applies a voltage to the gate electrode of the transistor and applies, to the source region and the drain region of the transistor, voltages that are opposite in polarity to the voltage applied to the gate electrode.

11. The driving method according to claim 10, further comprising a charge erasing step of erasing the charge stored in the charge storage portion by removing it into the semiconductor substrate, wherein during the removal of the charge the charge erasing step applies a voltage to the gate electrode of the transistor and applies, to the source region and the drain region of the transistor, voltages that are opposite in polarity to the voltage applied to the gate electrode.

12. A driving method of the imaging device according to claim 4, comprising a charge erasing step of erasing the charge stored in the charge storage portion by removing it into the semiconductor substrate, wherein during the removal of the charge the charge erasing step applies a voltage to the gate electrode of the transistor and applies, to the source region and the drain region of the transistor, voltages that are opposite in polarity to the voltage applied to the gate electrode.
